(19) United States
(12) Patent Application Publication
(10) Pub. No.: US 2025/0125121 A1
(43) Pub. Date: Apr. 17, 2025

(54) TWO-ELECTRODE CONTINUOUS PLASMA PROCESSING SYSTEM

(71) Applicant: UVAT TECHNOLOGY CO.,LTD., Taoyuan City (TW)

(72) Inventors: YUAN-CHI LEE, Taoyuan City (TW); PIN-CHUN LIU, Taoyuan City (TW); CHUN-CHIEH YANG, Taoyuan City (TW); MING-CHAN TSAI, Taoyuan City (TW); CHIH-MING LU, Taoyuan City (TW)

(21) Appl. No.: 18/380,216

(22) Filed: Oct. 16, 2023

(51) Int. Cl. H01J 37/32

(52) U.S. Cl. CPC H01J 37/32183; H01J 37/32568; H01J 37/32715; H01J 37/32761; H01J 2237/202

(57) ABSTRACT

A two-electrode continuous plasma processing system includes a processing chamber having a clamping device, a moving device, a first and a second electrodes, and a first and a second radio frequency power sources. When an object moves into a processing space of the processing chamber, the moving device controls the second electrode to drive the object to move toward the first electrode, and actuates the second electrode and the clamping device to clamp and fix the object. The first radio frequency power source provides the first electrode with a first radio frequency energy to control the density of plasma. The second radio frequency power source provides the second electrode with a second radio frequency energy to control the ion energy of the plasma. Therefore, the plasma is efficiently stabilized, lowering the probability of object damage.

### BACKGROUND OF THE INVENTION

### 1. Field of the Invention

The present invention relates to plasma processing techniques, and more particularly, to a two-electrode continuous plasma processing system.

### 2. Description of the Related Art

A conventional plasma processing machine uses a single radio frequency power source to supply radio frequency energy to the upper electrode and the lower electrode in the chamber for carrying out the plasma process of a to-be-processed object, such as a die, to-be-coated object, or to-be-etched object.

Based on the fact that the single radio frequency power source only provides the energy to one of the upper electrode and the lower electrode, with the other electrode being grounded at the same time, such power supply mechanism is only capable of fulfilling the process having smaller energy requirement, such as applying plasma to carry out a surface cleansing operation. However, such mechanism is unable to be applied to the process of etching or sputtering of metal surface having higher requirement. Also, during the plasma matching process between the upper electrode and the lower electrode, the plasma would be instable for a certain time duration. If the subsequent process proceeds before the plasma between the upper electrode and the lower electrode is efficiently stabilized and matched, the to-be-processed object will be severely damaged. Further, if the instable duration of the plasma lasts too long, the overall production progress will inevitably be affected.

### SUMMARY OF THE INVENTION

The present invention aims at resolving the issue of the plasma instability of the plasma processing machine, so as to lower the probability of damage of the to-be-processed object.

Another objective of the present invention is to provide a method of stably fixing the to-be-plated object of the continuous plasma processing system, so as to prevent the to-be-plated object from curving, detachment, and displacement during the plasma process.

For achieving the aforementioned objectives, the present invention provides a two-electrode continuous plasma processing system, comprising an uploading chamber, a processing chamber, and a downloading chamber. The uploading chamber is configured to input a to-be-processed object. The processing chamber is communicated with the uploading chamber for receiving the to-be-processed object and carrying out a plasma process on the to-be-processed object. The processing chamber comprises a controller, a clamping device, a moving device, and a first electrode, a second electrode, a first radio frequency power source, and a second radio frequency power source that are coupled with the controller. The first electrode and the second electrode are disposed on two opposite ends in the processing chamber and form a processing space. The clamping device is fixed in the processing space. The moving device is connected with the second electrode. When the to-be-processed object moves in the processing space, the moving device controls the second electrode to carry the to-be-processed object toward the first electrode, such that the second electrode and the clamping device clamp and fix the to-be-processed object. The first radio frequency power source is coupled with the first electrode and provides the first electrode with a first radio frequency energy to control a density of a plasma. The second radio frequency power source is coupled with the second electrode and provides the second electrode with a second radio frequency energy to control an ionic energy of the plasma. The downloading chamber is communicated with the processing chamber, and receives and outputs the processed object.

With such configuration, the two-electrode continuous plasma processing system applies the first radio frequency power source providing the energy to the first electrode and the second radio frequency power source providing the energy to the second electrode to control the power of the first electrode and the second electrode, thereby efficiently stabilizing the plasma between the first electrode and the second electrode and finishing the plasma matching, lowering the probability of damage of the to-be-processed object.

### BRIEF DESCRIPTION OF THE DRAWINGS

FIG. 1 is a perspective view of the plasma processing system in accordance with an embodiment of the present invention.

FIG. 2 is a structural block view of the processing chamber of the plasma processing system in accordance with an embodiment of the present invention.

FIG. 3 is a sectional view of the chamber of the plasma processing system in accordance with an embodiment of the present invention.

FIG. 4 is a partially enlarged view of FIG. 3, illustrating the moving device carrying the second electrode toward the first electrode.

FIG. 5 is another partially enlarged view of FIG. 3, illustrating the clamping device cooperating with the second electrode to fix the to-be-processed object.

FIG. 6 is a schematic view of the circuit of the plasma processing system in accordance with an embodiment of the present invention.

FIG. 7 is another schematic view of the circuit of the plasma processing system, illustrating the first radio frequency power source actuating the first electrode to generate the low-density plasma, and the second radio frequency power source actuating the second electrode to generate the low ion energy plasma.

FIG. 8 is another schematic view of the circuit of the plasma processing system, illustrating the first radio frequency power source actuating the first electrode to generate the high-density plasma, and the second radio frequency power source actuating the second electrode to generate the high ion energy plasma.

### DETAILED DESCRIPTION OF THE INVENTION

The aforementioned and further advantages and features of the present invention will be understood by reference to the description of the preferred embodiment in conjunction with the accompanying drawings where the components are illustrated based on a proportion for explanation but not subject to the actual component proportion.

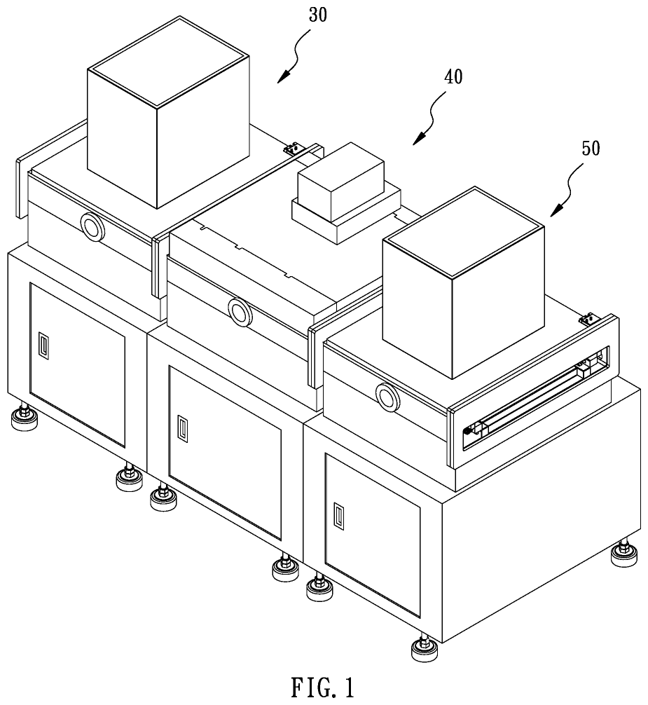

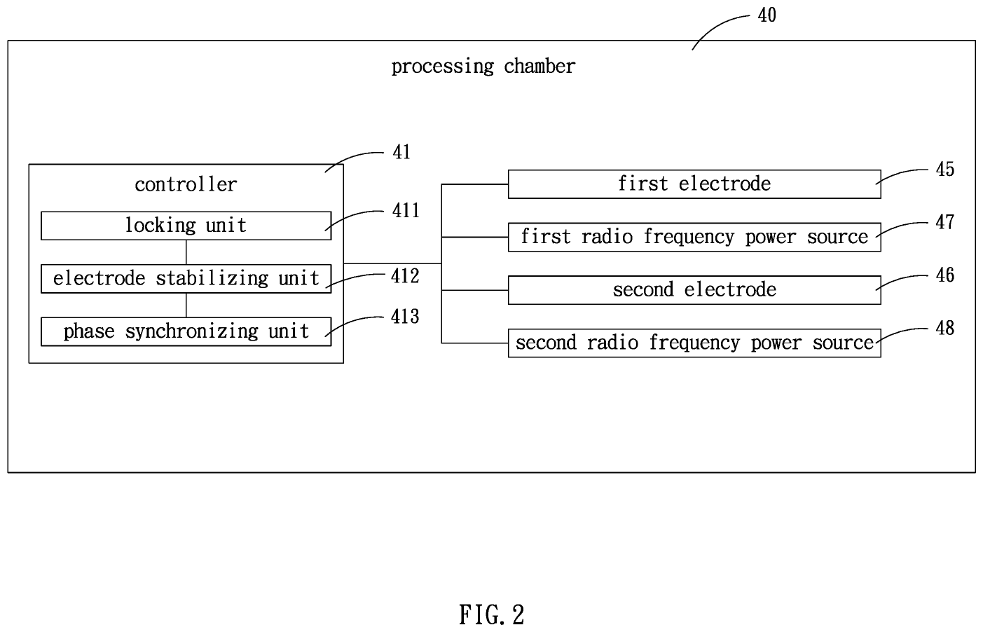

Referring to FIG. 1 to FIG. 8, the present invention provides a two-electrode continuous plasma processing system, comprising a carrier plate 10, a conveying device 20, and an uploading chamber 30, a processing chamber 40, and a downloading chamber 50 that are orderly connected.

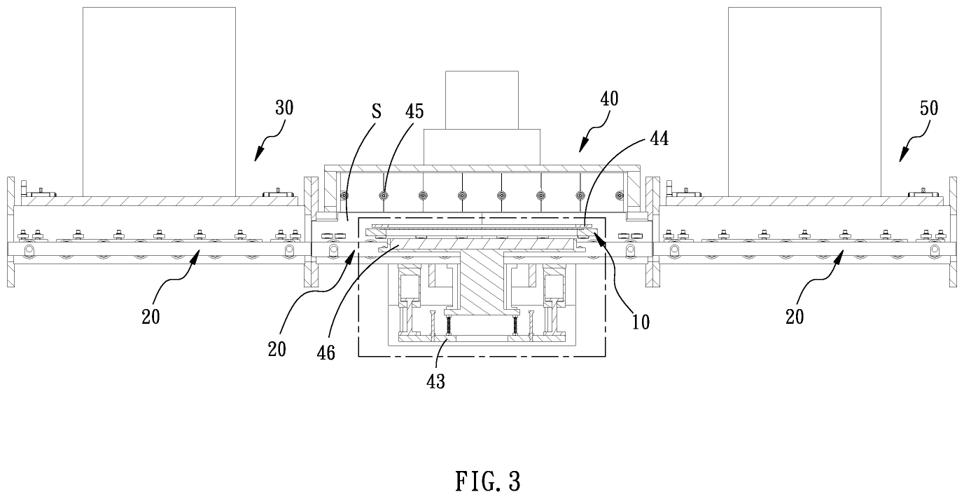

In the present invention, the uploading chamber 30, the processing chamber 40, and the downloading chamber 50 are communicated with each other. The conveying device 20 is continuously disposed in the uploading chamber 30, the processing chamber 40, and the downloading chamber 50 (as shown by FIG. 3). The uploading chamber 30 is configured to input a to-be-processed object 1. The processing chamber 40 is configured to receive the to-be-processed object 1 and carry out a plasma process on the to-be-processed object 1. The downloading chamber 50 is configured to receive and output the finished to-be-processed object 1.

The carrier plate 10 comprises a frame shape holding part 11 for holding the to-be-processed object 1. The carrier plate 10 is placed on the conveying device 20 and conveyed by the conveying device 20, so as to horizontally move the to-be-processed object 1 from the uploading chamber 30 into the processing chamber 40 toward the downloading chamber 50.

The processing chamber 40 comprises a controller 41, a positioning device 42, a moving device 43, a clamping device 44, and a first electrode 45, a second electrode 46, a first radio frequency power source 47, and a second radio frequency power source 48 that are coupled with the controller 41.

The first electrode 45 and the second electrode 46 are disposed on two opposite ends in the processing chamber 40 to form a processing space S. The clamping device 44 and the positioning device 42 are disposed in the processing space S. The moving device 43 is connected with the second electrode 46.

When the carrier plate 10 enters the processing chamber 40 from the uploading chamber 30, the positioning device 42 is configured to detect if the carrier plate 10 is at a processing position in the processing space S. In the embodiment, the positioning device 42 is a photoelectric sensor, comprising a light projecting part and a corresponding light receiving part. When the carrier plate 10 moves to the processing position, the carrier plate 10 intercepts the light beam between the light projecting part and the light receiving part, such that the positioning device 42 confirms that the carrier plate 10 reaches the processing position.

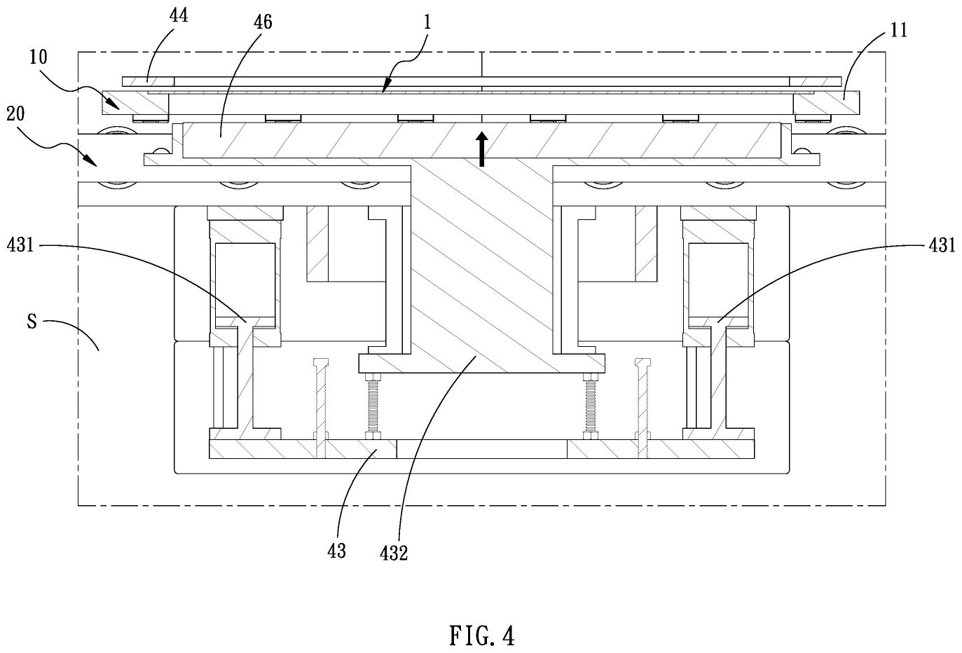

Referring to FIG. 4, after the confirmation of the carrier plate 10 reaching the processing position, the moving device 43 controls the second electrode 46 to pass the frame shape holding part 11 and drive the to-be-processed object 1 toward the first electrode 45, so that the to-be-processed object 1 leaves the frame shape holding part 11. Therein, the moving device 43 comprises a driving member 431 and a lifting member 432 connected with the driving member 431. The driving member 431 is configured to drive the lifting member 432 to move toward the first electrode 45 to contact the second electrode 46, so that the second electrode 46 passes through the frame shape holding part 11. In the embodiment, the driving member 431 is allowed to be a pneumatic cylinder or hydraulic cylinder.

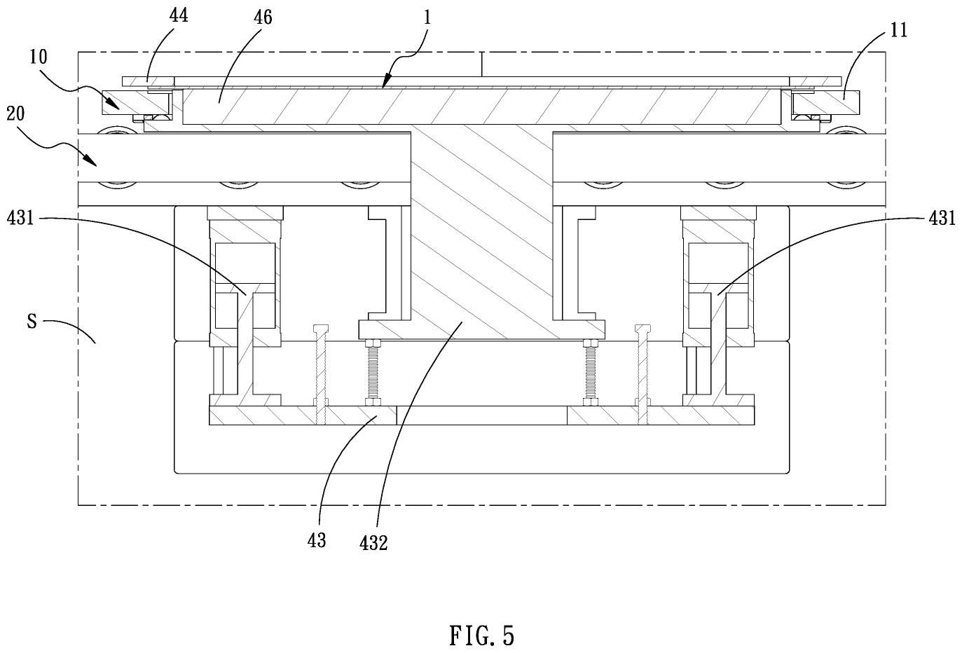

Referring to FIG. 5, the clamping device 44 is fixed in the processing space S. After the moving device 43 controls the second electrode 46 to carry the to-be-processed object 1 toward the first electrode 45 and leave the frame shape holding part 11, the second electrode 46 and the clamping device 44 clamp and fix the to-be-processed object 1. In the embodiment, the clamping device 44 is a rectangular frame body. The clamping device 44 is configured to cooperate with the second electrode 46 to position the outer edge of the to-be-processed object 1, so as to prevent the to-be-processed object 1 from hot bending to affect the etching or coating effect.

In the embodiment, after the plasma process is finished, the moving device 43 controls the second electrode 46 to move away from the first electrode 45, such that the to-be-processed object 1 is held on the frame shape holding part 11, moving toward the downloading chamber 50 through the conveying device 20.

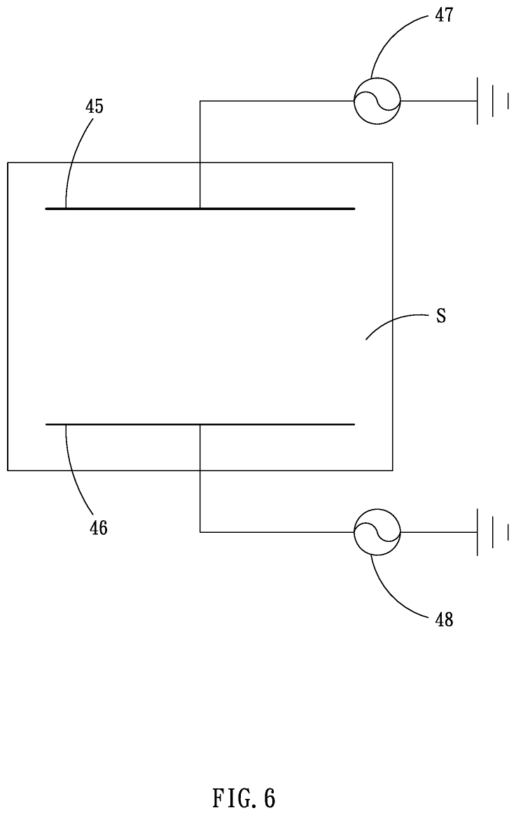

Referring to FIG. 6 to FIG. 8, the first radio frequency power source 47 is coupled with the first electrode 45, and provides the first electrode 45 with a first radio frequency energy to control the density of the plasma; the second radio frequency power source 48 is coupled with the second electrode 46, and provides the second electrode 46 with a second radio frequency energy to control the ion energy of the plasma.

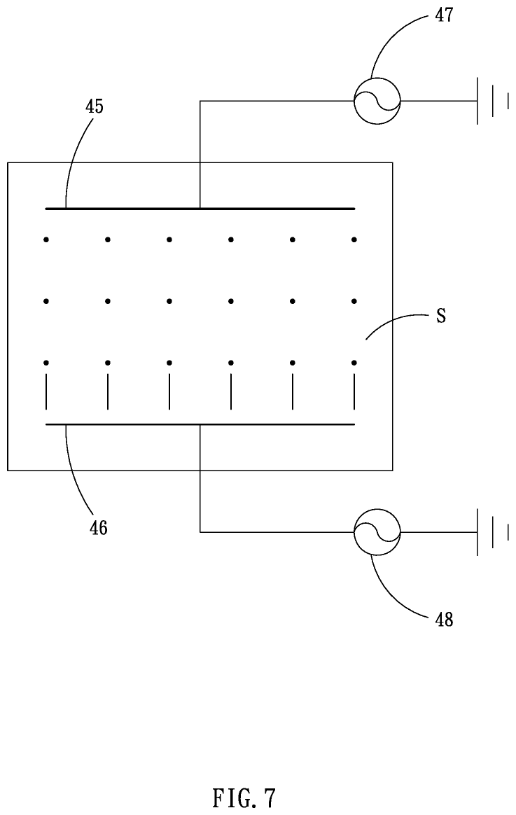

In the embodiment, as shown by FIG. 7, the first radio frequency power source 47 provides the first radio frequency energy having a low power to control the first electrode 45 to generate the low-density plasma. The second radio frequency power source 48 provides the second radio frequency energy having a low power to control the second electrode 46 to generate the low ion energy plasma.

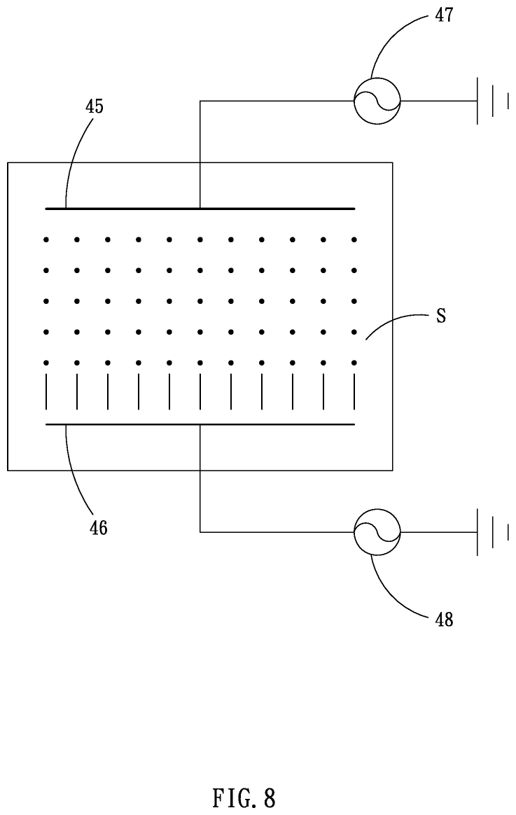

Referring to FIG. 8, the first radio frequency power source 47 provides the first radio frequency energy having a high power to control the first electrode 45 to generate the high-density plasma. The second radio frequency power source 48 provides the second radio frequency energy having a high power to control the second electrode 46 to generate the high ion energy plasma.

The controller 41 comprises a locking unit 411, an electrode stabilizing unit 412, and a phase synchronizing unit 413.

The locking unit 411 is configured to control the activation of the second radio frequency power source 48. In the embodiment, the second radio frequency power source 48 is initially in a locked status. When the first radio frequency energy provided by the first radio frequency power source 47 reaches an initial power, the locking unit 411 unlocks the locked status of the second radio frequency power source 48, allowing the second radio frequency power source 48 provides the second radio frequency energy to the second electrode 46, so as to prevent the instability of the plasma generation.

The electrode stabilizing unit 412 is configured to adjust the power output of the first radio frequency power source 47 and the second radio frequency power source 48 when the plasma is in a stable status. In the embodiment, when the first radio frequency energy and the second radio frequency energy reach the initial power, the electrode stabilizing unit 412 controls the first radio frequency 47 to increase the first radio frequency energy to a first processing power; when the first radio frequency energy reaches the first processing power, the electrode stabilizing unit 412 controls the second radio frequency power source 48 to increase the second radio frequency energy to a second processing power.

In the embodiment, the initial power is 0.5 kW; the first processing power and the second processing power range from 1 kW to 5 kW.

The plasma power adjustment process between the first electrode 45 and the second electrode 46 during the processing chamber 40 carrying out the plasma process on the to-be-processed object 1 will be illustrated below.

First, the first radio frequency power source 47 is activated to provides the first electrode 45 with the first radio frequency energy.

When the first radio energy reaches the initial power, the locking unit 411 unlocks the locked status of the second radio frequency power source 48, and controls the second radio frequency power source 48 to provide the second electrode 46 with the second radio frequency energy.

When the second radio frequency energy reaches the initial power as well, the electrode stabilizing unit 412 controls the first radio frequency power source 47 to increase the first radio frequency energy to the first processing power.

When the first radio frequency energy is increased to the first processing power, the electrode stabilizing unit 412 continues to control the second radio frequency power source 48 to increase the second radio energy to the second processing power, finishing the power adjustment.

Therefore, the first radio frequency power source 47 and the second radio frequency power source 48 control the power of the first electrode 45 and the second electrode 46, respectively, whereby the plasma between the first electrode 45 and the second electrode 46 is efficiently stabled and matched, lowering the damage probability of the to-be-processed object 1 and achieving the ideal plasma etching or coating effect. In the embodiment, the time duration needed for plasma stabilizing and power adjusting processes is 3 to 5 seconds.

The phase synchronizing unit 413 is configured to make the first radio frequency power source 47 and the second radio frequency power source 48 achieve a phase-matching status. Therein, the phase matching operation is to adjust the phases of the first radio frequency power source 47 and the second radio frequency power source 48, whereby there is a fixed phase difference, such as 0, 90, 180, or 270 degrees, between the first radio frequency power source 47 and the second radio frequency power source 48, so that the plasma between the first electrode 45 and the second electrode 46 is evenly distributed in the processing space S.

With the foregoing configuration, the present invention achieves following advantages.

The first radio frequency power source 47 and the second radio frequency power source 48 control the power of the first electrode 45 and the second electrode 46, respectively, such that the plasma between the first electrode 45 and the second electrode 46 is efficiently stabled and matched, lowering the damage probability of the to-be-processed object 1, and preventing the production progress from being affected.

Instead of using a single power source to provide energy to the first electrode 45 and the second electrode 46, the present invention applies the first radio frequency energy provided by the first radio frequency power source 47 to control the density of the plasma, and applies the second radio frequency energy provided by the second radio frequency power source 48 to control the ion energy of the plasma, thereby providing the processing flexibility to fulfill different processing requirements.

With the fixed clamping device 44 and the moving device 43 driving the second electrode 46 toward the first electrode 45, the to-be-processed object 1 is clamped and fixed, thereby preventing the to-be-process object 1 from bending to affect the etching or coating effect.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A two-electrode continuous plasma processing system, comprising:
an uploading chamber for inputting a to-be-processed object;
a processing chamber communicated with the uploading chamber for receiving the to-be-processed object and carrying out a plasma process on the to-be-processed object, the processing chamber comprising a controller, a clamping device, a moving device, and a first electrode, a second electrode, a first radio frequency power source, and a second radio frequency power source that are coupled with the controller, the first radio frequency power source and the second radio frequency power source being disposed on two opposite ends in the processing chamber and forming a processing space, the clamping device fixed in the processing space, the moving device connected with the second electrode; when the to-be-processed object moves into the processing space, the moving device controls the second electrode to drive the to-be-processed object to move toward the first electrode, such that the second electrode and the clamping device clamp and fix the to-be-processed object, the first radio frequency power source being coupled with the first electrode and providing the first electrode with a first radio frequency energy to control a density of a plasma, the second radio frequency power source being coupled with the second electrode and providing the second electrode with a second radio frequency energy to control an ion energy of the plasma; and
a downloading chamber communicated with the processing chamber for receiving and outputting the finished to-be-processed object.

2. The two-electrode continuous plasma processing system of claim 1, further comprising a carrier plate, the carrier plate comprises a frame shape holding part for holding the to-be-processed object; the moving device controls the second electrode to pass through the frame shape holding part and drive the to-be-processed object to move toward the first electrode, so that the to-be-processed object leaves the frame shape holding part.

3. The two-electrode continuous plasma processing system of claim 2, wherein the processing chamber comprises a positioning device configured to detect if the carrier plate is at a processing position in the processing space.

4. The two-electrode continuous plasma processing system of claim 1, wherein the clamping device is a rectangular frame body.

5. The two-electrode continuous plasma processing system of claim 1, wherein the controller comprises a locking unit; when the first radio frequency energy provided by the first radio frequency power source reaches an initial power, the locking unit unlocks a locked status of the second radio frequency power source, so that the second radio frequency power source provides the second electrode with the second radio frequency energy.

6. The two-electrode continuous plasma processing system of claim 5, wherein the controller comprises an electrode stabilizing unit; when the first radio frequency energy and the second radio frequency energy reach the initial power, the electrode stabilizing unit actuates the first radio frequency power source to increase the first radio frequency energy to a first processing power.

7. The two-electrode continuous plasma processing system of claim 6, wherein the initial power is 0.5 kW.

8. The two-electrode continuous plasma processing system of claim 6, wherein when the first radio frequency energy is increased to the first processing power, the electrode stabilizing unit actuates the second radio frequency power source to increase the second radio frequency energy to a second processing power.

9. The two-electrode continuous plasma processing system of claim 8, wherein the first processing power and the second processing power range from 1 kW to 5 kW.

10. The two-electrode continuous plasma processing system of claim 1, wherein the controller further comprises a phase synchronizing unit; the phase synchronizing unit is configured to make the first radio frequency power source and the second radio frequency power source achieve a phase-matching status.
